(19) United States
(12) Patent Application Publication
(10) Pub. No.: US 2012/0080091 A1
(43) Pub. Date: Apr. 5, 2012

(54) FABRICATION OF CIS OR CIGS THIN FILM FOR SOLAR CELLS USING PASTE OR INK

(76) Inventors: Byoung Koun Min, Seoul (KR); Se Jin Park, Seoul (KR)

(21) Appl. No.: 12/986,749

(22) Filed: Jan. 7, 2011

(30) Foreign Application Priority Data
Oct. 4, 2010 (KR) 10-2010-0096381

(51) Int. Cl. H01L 31/0256

(52) U.S. Cl. 136/262; 438/95; 257/E31.003

(57) ABSTRACT

Provided is a method for preparing a copper indium selenide (CIS) or copper indium gallium selenide (CIGS) thin film, including: (1) mixing Cu, In and Ga precursors in a solvent and adding a polymer binder to obtain a paste or ink; (2) coating the obtained CIG precursor paste or ink on a conductive substrate by printing, spin coating or spraying and heat-treating the same under air or oxygen gas atmosphere to remove remaining organic substances and obtain a CIG mixed oxide thin film; (3) heat-treating the obtained CIG mixed oxide thin film under hydrogen or sulfurizing gas atmosphere to obtain a reduced or sulfurized CIG mixed thin film; and (4) heat-treating the obtained reduced or sulfurized CIG mixed thin film under selenium-containing gas atmosphere to obtain a CIGS thin film. Since residual carbon resulting from organic additives, which is the biggest problem in the existing paste coating techniques, can be reduced remarkably, and CIGS crystal size can be improved, the disclosed method can improve efficiency of CIGS solar cells.

### CROSS-REFERENCE TO RELATED APPLICATIONS

This application claims priority under 35 U.S.C. §119 to Korean Patent Application No. 10-2010-0096381, filed on Oct. 4, 2010, in the Korean Intellectual Property Office, the disclosure of which is incorporated herein by reference in its entirety.

### TECHNICAL FIELD

The present disclosure relates to a method for preparing a copper indium selenide (CIS) or copper indium gallium selenide (CIGS) thin film that can be used in a thin-film solar cell as a light-absorbing layer. More specifically, the disclosure relates to a method for preparing a CIS or CIGS thin film capable of remarkably reducing residual carbon and improving CIGS crystal size, thus capable of improving efficiency of a CIGS solar cell prepared by a printing method.

### BACKGROUND

A solar cell which can produce electricity directly from the sunlight is the most promising future energy source since clean energy can be produced safely. Various inorganic and organic semiconductors are used to manufacture the solar cells. At present, typical examples that have reached the level of commercialization are silicon solar cells using primarily silicon (Si) and copper indium gallium selenide (CIGS) thin-film solar cells.

Although silicon solar cells exhibit high photoconversion efficiency, manufacture cost of them is high. Thus, thin-film solar cells that use compound semiconductors and allow application of thinner films are drawing a lot of attentions.

A representative example of the thin-film solar cell is one using group IB, IIIA and VIA elements in a light-absorbing layer, also known as a copper indium selenide (CIS) or CIGS thin-film solar cell. In this kind of solar cell, the light-absorbing layer generally composed of Cu(In,Ga)Se₂ and a buffer layer composed of CdS or other n-type compound semiconductor are of key importance. In particular, the CIS or CIGS light-absorbing layer is the most important factor that determines the performance of the solar cell.

The CIS or CIGS light-absorbing layer is typically prepared through co-evaporation or sputtering of metal elements. Specifically, the CIS or CIGS thin film may be deposited by co-evaporation of typically three components through several stages or by sputtering of Cu, In and Ga metal targets, followed by selenization. However, it requires expensive vacuum apparatuses since all the processes are performed in vacuum conditions. Further, the vacuum conditions are disadvantageous in that the expensive indium or gallium is lost greatly, it is difficult to attain a large size, and the processing speed cannot be increased.

Methods for producing a CIGS thin film by an inexpensive chemical process without requiring the vacuum apparatus are known. In particular, preparation of the CIGS thin film by the printing method is the most promising in terms of production speed, production cost and area enlargement. The preparation of the CIGS thin film by printing may be divided into a method using an ink or paste of precursors and one preparing CIG or CIGS nanoparticles and dispersing them in an ink or paste for printing.

As an example of the precursor method, binary compounds such as Cu₂S, In₂Se₃ and Ga₂Se were dissolved in hydrazine solvent to prepare a precursor ink, which was then applied on a conductive substrate and heat-treated under nitrogen atmosphere to prepare a CIGS thin film [Mitzi et al. Advanced Materials, 2008, 20, 3657-3662]. Also, Cu, In and Ga nitrates and SeCl₄ were dissolved in alcohol solvent and mixed with an organic binder to generate a paste, which was then applied on a conductive substrate and heat-treated under H₂/Ar atmosphere to prepare a CIGS thin film.

As examples of the nanoparticle method, CIGS nanoparticles were synthesized and dispersed, and then applied on a conductive substrate and heat-treated to give a CIGS thin film [US Patent Application No. 2006-0062902], and CuInGa oxide nanoparticles were synthesized and dispersed, and then applied on a conductive substrate and heat-treated under H₂Se gas atmosphere to prepare a CIGS thin film [Kapur et al. Thin Solid Films 2003, 431-432, 53-57].

These methods are associated with the problem that, use of the organic solvent and the organic additives such as polymer binder for the preparation of the paste or ink results in a large amount of carbon impurities remaining after heat treatment under hydrogen or nitrogen atmosphere. Even when a selenization process is employed using the toxic H₂Se or Se gas, carbon impurities resulting from decomposition of the organic substances remain, causing decreased solar cell efficiency. When hydrazine is used as a solvent, the residual carbon may be reduced. However, because hydrazine is highly toxic and explosive, its industrial use is undesirable.

In order to solve the problems of the existing preparation methods of CIGS thin films by printing, a preparation method capable of minimizing residual carbon impurities even when a stable organic solvent is used is necessary. In addition, the minimization of residual carbon will result in increased CIGS crystal size, which is one of the most important factors in a CIGS light-absorbing layer, thereby enabling the preparation of a high-efficiency thin-film solar cell.

### SUMMARY

The present disclosure is directed to providing a method for preparing a high-quality copper indium selenide (CIS) or copper indium gallium selenide (CIGS) thin film capable of minimizing residual carbon impurities in order to prepare a CIS or CIGS solar cell through an inexpensive printing method.

The present disclosure is also directed to providing a CIS or CIGS thin film for a solar cell including minimal residual carbon impurities.

The present disclosure is also directed to providing a high-efficiency solar cell using a CIS or CIGS thin film including minimal residual carbon impurities and having improved CISG crystal size.

In one general aspect, the present disclosure provides a method for preparing a CIS or CIGS thin film, including: (1) mixing Cu, In and Ga precursors in a solvent and adding a polymer binder to obtain a paste or ink; (2) coating the obtained CIG precursor paste or ink on a conductive substrate by printing, spin coating or spraying and heat-treating the same under air or oxygen gas atmosphere to remove remaining organic substances and obtain a mixed oxide thin film of Cu, In, and Ga; (3) heat-treating the obtained a mixed oxide thin film of Cu, In, and Ga under hydrogen or sulfurizing gas atmosphere to obtain a reduced or sulfurized the mixed oxide thin film; and (4) heat-treating the obtained reduced or sulfurized the mixed oxide thin film under selenium-containing gas atmosphere to obtain a CIGS thin film.

In another general aspect, the present disclosure provides a CIS or CIGS thin film for a solar cell prepared by the afore-described method and having 1 at % or less residual carbon.

In another general aspect, the present disclosure provides a high-efficiency solar cell including the CIS or CIGS thin film having 1 at % or less residual carbon.

Other features and aspects will be apparent from the following detailed description, the drawings, and the claims.

### BRIEF DESCRIPTION OF THE DRAWINGS

The above and other objects, features and advantages of the present disclosure will become apparent from the following description of certain exemplary embodiments given in conjunction with the accompanying drawings, in which:

FIG. 1 is a block diagram illustrating a process of preparing a copper indium selenide (CIS) or copper indium gallium selenide (CIGS) thin film according to the present disclosure;

FIG. 2 shows an XRD pattern of a CuInGa mixed oxide thin film synthesized from Cu, In, and Ga nitrate precursors;

FIG. 3 shows an SEM image of a CuInGa mixed oxide thin film;

FIG. 4 shows an SEM image of a CIGS thin film obtained by heat-treating a CuInGa mixed oxide thin film at 500° C. under H₂S/Ar gas atmosphere;

FIG. 5 shows an XRD pattern of a CIGS thin film obtained by heat-treating a sulfurized CuInGaS₂ thin film at 500° C. under Se vapor/Ar gas atmosphere;

FIG. 6 shows an SEM image of a CIGS thin film obtained by heat-treating a sulfurized CuInGaS₂ thin film at 500° C. under Se vapor/Ar gas atmosphere; and

FIG. 7 shows SEM images comparing crystal size of a CIGS thin film obtained according to the present disclosure with that of the existing CIGS thin film.

It should be understood that the appended drawings are not necessarily to scale, presenting a somewhat simplified representation of various preferred features illustrative of the basic principles of the disclosure. The specific design features of the disclosure as disclosed herein, including, for example, specific dimensions, orientations, locations and shapes, will be determined in part by the particular intended application and use environment.

In the figures, reference numerals refer to the same or equivalent parts of the disclosure throughout the several figures of the drawings.

### DETAILED DESCRIPTION OF EMBODIMENTS

The advantages, features and aspects of the present disclosure will become apparent from the following description of the embodiments with reference to the accompanying drawings, which is set forth hereinafter. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The terminology used herein is for the purpose of describing particular embodiments only and is not intended to be limiting of the example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Hereinafter, exemplary embodiments will be described in detail with reference to the accompanying drawings.

In the present description, CIS or CIGS refers to a copper indium selenide or copper indium gallium selenide thin film having the composition of Cu(In,Ga)(S,Se)₂.

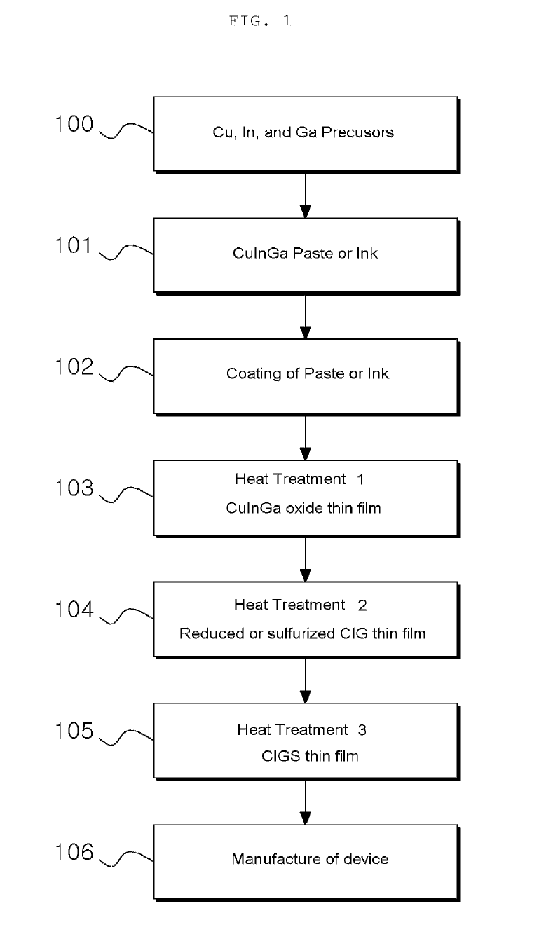

Now, preparation of a CIG precursor paste or ink and preparation of a CIGS thin film using the same will be described referring to FIG. 1.

As shown in FIG. 1, in the step (1), Cu, In and Ga precursors are prepared (100). The precursors are dissolved in a solvent by stirring and then mixed with a polymer binder and an organic additive to prepare a CIG precursor paste or ink (101).

The Cu, In or Ga precursor may be a hydroxide, a nitrate, a sulfate, an acetate, a chloride, an acetylacetonate, a formate or an oxide of the corresponding metal or a combination thereof.

The solvent used to dissolve the Cu, In and Ga precursors may be selected, for example, from water, alcohol, acetone, or the like.

During the mixing and stirring, one or more of a dispersant and a binder may be added to the precursor mixture depending on the purpose of the obtained paste or ink.

The dispersant or binder may be selected from those commonly used in the art. Examples of the dispersant include α-terpineol, ethylene glycol, thioacetamide, ethylenediamine, etc., and examples of the binder include ethyl cellulose, palmitic acid, polyethylene glycol, polypropylene glycol, polypropylene carbonate, polyvinyl acetate, etc. The content of the dispersant or binder is not particularly limited. For example, each of them may be used in an amount of about 10-400 wt % based on the total weight of the precursor mixture.

The metal precursor mixture may further comprise a dopant component to improve efficiency of a solar cell in which the final thin film will be used. The dopant component may be Na, K, Ni, P, As, Sb, Bi or a combination thereof. The dopant component may be any compound capable of generating the corresponding metal ion in the reaction system, and may be used in an amount of about 1-100 wt % based on the total weight of the precursor mixture.

Next, in the step (2), the obtained paste or ink is coated on a substrate and heat-treated under air or oxygen atmosphere to prepare a CIG mixed oxide thin film (102). The substrate may be made of a conductive material capable of enduring high temperature of, for example, 300° C. or above. For example, indium tin oxide (ITO) or fluorine-doped indium tin oxide (FTO) glass, Mo-coated glass, metal foil, metal plate or conductive polymer material may be used. Also, a substrate prepared by forming a conductive thin film layer on a non-conductive substrate may be used.

The coating may be performed according to common methods, for example, by doctor blade coating, spin coating, screen printing or spraying. A coating thickness may be 0.5-50 μm.

The heat treatment following the coating is performed under air or oxygen gas atmosphere at 200-700° C., specifically at 350-550° C. (103). This procedure is carried out to remove residual carbon resulting from the organic solvent, the organic additive, the polymer binder, etc. used to prepare the paste or ink. As a result, a CIG mixed oxide thin film having 1 at % or less residual carbon may be obtained.

Next, in the step (3), the prepared CIG mixed oxide thin film is reduced or sulfurized under hydrogen or sulfur atmosphere (104). The reduction or sulfurization may be performed by heat treatment under H₂ or H₂S gas atmosphere. Further, it may be performed by heat treatment under atmosphere of a mixture thereof with an inert gas. The heat treatment temperature may be different depending on the particular conductive substrate. Specifically, it may be performed at 400-600° C.

Next, in the step (4), the prepared reduced or sulfurized CIG mixed thin film is reacted under selenium atmosphere to obtain a CIGS thin film (105). The heat treatment temperature may be different depending on the particular conductive substrate. Specifically, the heat treatment may be performed at 400-600° C. Although H₂Se gas may be used as a selenium source, Se vapor may be used instead since H₂Se is toxic.

As described, the method for preparing a CIS or CIGS thin film according to the present disclosure employs a printing method using a paste or ink rather than the co-evaporation or sputtering method of the existing preparation techniques. As a result, material loss during the production of a CIS or CIGS solar cell can be reduced, and mass production, area enlargement and production speed improvement are possible. Since the CIGS thin film is prepared by coating a paste or ink comprising precursors of the respective elements and then completely removing organic substances, unlike the previous printing methods, restriction of CIGS crystal size growth caused by residual carbon impurities and low solar cell efficiency resulting therefrom may be resolved. Further, since the CIG precursor is used rather than CIG oxide nanoparticles or CIGS nanoparticles, thin films with easily controllable elemental compositions and various energy gaps may be prepared. Thus, it is applicable to tandem thin-film solar cells having thin films with different energy gaps.

Besides, the method according to the present disclosure is usefully applicable to manufacture of light-absorbing layers for solar cells comprising group IB, IIIA and VIA elements, in addition to the CIS or CIGS thin films.

### EXAMPLES

The examples and experiments will now be described. The following examples and experiments are for illustrative purposes only and not intended to limit the scope of this disclosure.

### Example 1

### Preparation of CIG Mixed Oxide Thin Film from CIG Precursor Paste

First, in order to prepare a CIG precursor paste, Cu(NO₃)₂.×H₂O (1 g, 5 mmol), Ga(NO₃)₃.×H₂O (0.4 g, 1.6 mmol) and In(NO₃)₃.×H₂O (1.12 g, 3.7 mmol) were dissolved in ethanol (100 mL) and then mixed with an ethanol solution (40 mL) of terpineol (15 g) and ethyl cellulose (0.75 g) under stirring.

Then, the solvent ethanol was evaporated at 40° C. for 30 minutes to obtain a CIG precursor paste having an adequate viscosity.

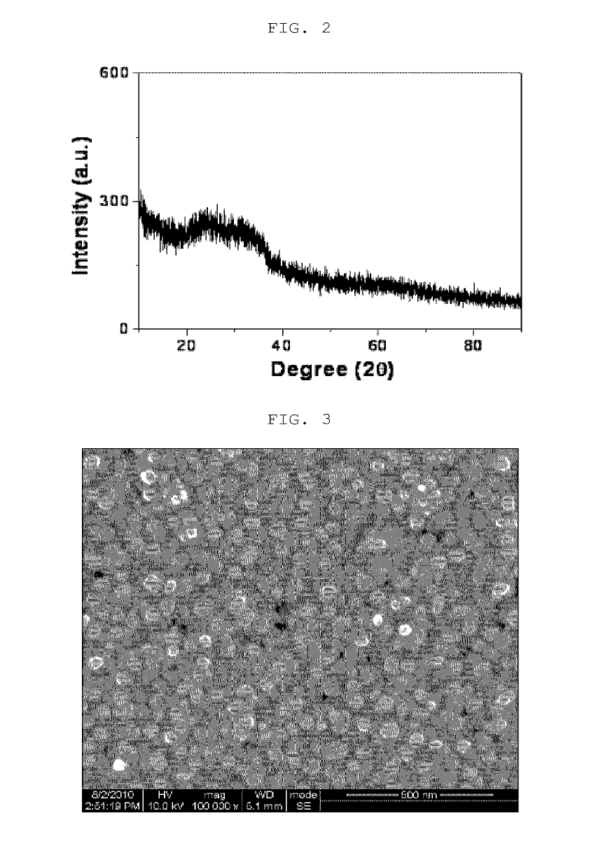

The paste was coated on an FTO glass substrate by doctor blade coating or spin coating and then heat-treated at 450° C. for 40 minutes under air atmosphere to obtain a CIG mixed oxide thin film. An XRD pattern of the CIG oxide thin film is shown in FIG. 2. Also, the morphology of the thin film was analyzed by SEM (FIG. 3). XRD pattern analysis revealed that the prepared CIG oxide thin film has an amorphous structure and the CIG oxide nanoparticles constituting the thin film were 10-50 nm in size. EPMA analysis revealed that the content of residual carbon impurities in the thin film was 1 at % or lower.

The XRD pattern analysis was performed with XRD-6000 (Shimadzu, Japan), the SEM analysis was performed with S-4200 (Hitachi, Japan), and the residual carbon measurement was performed with JXA-8500F EPMA.

### Example 2

### Preparation of CIGS Thin Film Through Sulfurization of CIG Mixed Oxide Thin Film

In order to prepare a CIGS thin film through sulfurization of the CIG oxide thin film, the obtained CIG oxide thin film was heat-treated at 500° C. for 40 minutes under H₂S (1000 ppm)/Ar mixture gas atmosphere.

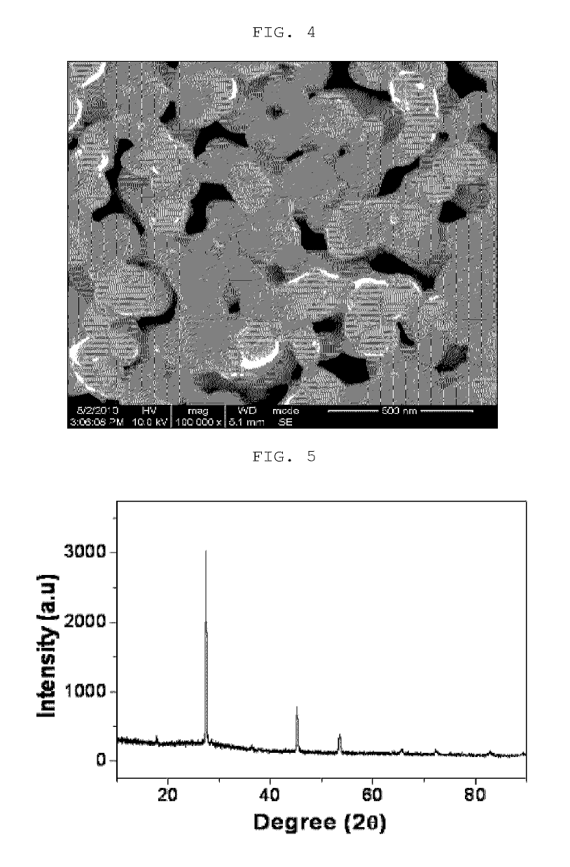

The morphology of thus obtained CIGS thin film was analyzed by SEM (FIG. 4).

### Example 3

### Preparation of CIGS Thin Film Through Selenization of Sulfurized CIG Thin Film

The thin film obtained through the sulfurization of the CIG oxide thin film was heat-treated at 500° C. for 40 minutes under Se/Ar gas atmosphere to prepare a CIGS thin film.

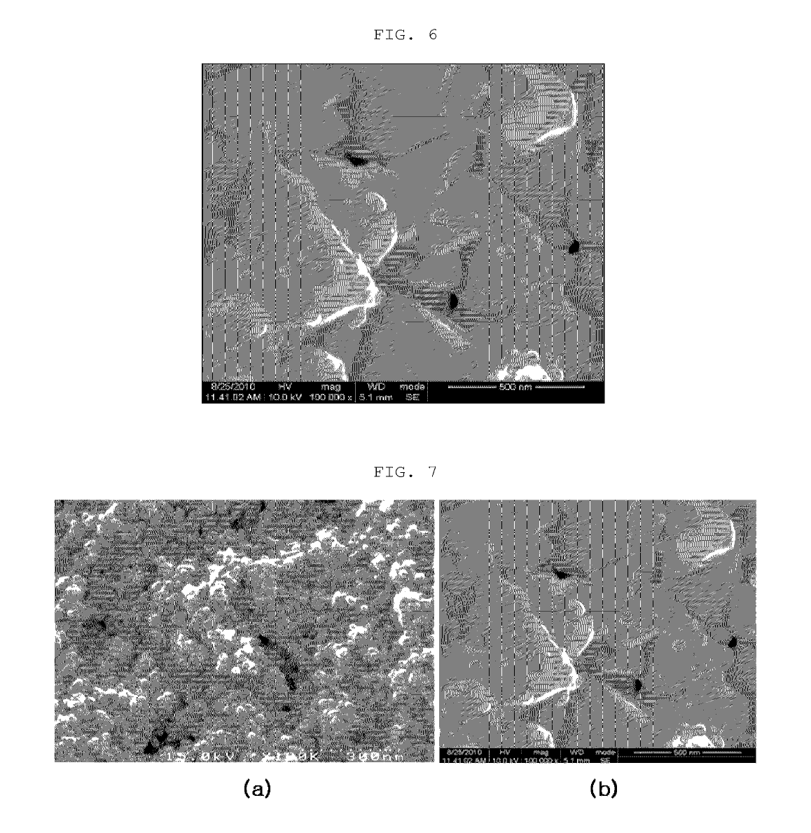

XRD pattern analysis of the obtained CIGS thin film is shown in FIG. 5. The morphology of the CIGS thin film was analyzed by SEM (FIG. 6).

The XRD pattern analysis was performed with XRD-6000 (Shimadzu, Japan). The presence of the (112) peak and the (220)/(204) peaks characteristic of CIS or CIGS confirmed that the CIGS thin film was prepared.

Also, the SEM image confirmed the growth of the CIGS particles constituting the thin film. EPMA analysis revealed that the content of residual carbon impurities in the thin film was 1 at % or lower.

### Comparative Example 1

### Comparison of Residual Carbon and Crystal Size with Existing CIGS Thin Film

A CIGS thin film prepared according to the existing method, without removal of residual carbon resulting from the organic solvent, the organic additive, the polymer binder, etc. used to prepare the paste or ink, had 60 at % or more residual carbon. Even after sulfurization or selenization of the CIGS thin film, 10 at % or more residual carbon was detected. In contrast, as described above in the foregoing examples, the CIGS thin film according to the present disclosure in which the paste or ink coating was heat-treated at high temperature under air or oxygen gas atmosphere, had 1 at % or less residual carbon.

FIG. 7 (a) is an SEM image of the CIGS thin film according to the existing art, and (b) is an SEM image of the CIGS thin film according to the present disclosure. It can be seen that the CIGS thin film according to the present disclosure has improved quality in terms of crystal shape and size.

As described, the present disclosure allows preparation of a CIS or CIGS thin film using a CuInGa precursor paste or ink without requiring a vacuum apparatus. Further, the production cost can be reduced since loss of metal sources is minimized, and decrease in efficiency can be prevented since residual carbon impurities can be minimized. In addition, the method according to the present disclosure is applicable to various types of substrates. Besides, since elemental compositions can be easily controlled and energy band gaps may be controlled depending on the compositions, the method allows voltage and current control of solar cells and thus is applicable to tandem thin-film solar cells.

While the present disclosure has been described with respect to the specific embodiments, it will be apparent to those skilled in the art that various changes and modifications may be made without departing from the spirit and scope of the disclosure as defined in the following claims.

What is claimed is:

1. A method for preparing a copper indium selenide (CIS) or copper indium gallium selenide (CIGS) thin film, comprising:
mixing Cu, In and Ga precursors in a solvent and adding a polymer binder to obtain a paste or ink;
coating the obtained CIG precursor paste or ink on a conductive substrate by printing, spin coating or spraying and heat-treating the same under air or oxygen gas atmosphere to remove remaining organic substances and obtain a CIG mixed oxide thin film;
heat-treating the obtained CIG mixed oxide thin film under hydrogen or sulfurizing gas atmosphere to obtain a reduced or sulfurized CIG thin film; and
heat-treating the obtained reduced or sulfurized CIG mixed thin film under selenium-containing gas atmosphere to obtain a CIGS thin film.

2. The method for preparing a CIS or CIGS thin film according to claim 1, wherein the Cu, In or Ga precursor is one capable of generating each metal ion in a solvent and is one or more selected from a hydroxide, a nitrate, a sulfate, an acetate, a chloride, an acetylacetonate, a formate or an oxide of said each metal ion or a combination thereof.

3. The method for preparing a CIS or CIGS thin film according to claim 1, wherein the Cu, In and Ga precursors are used in a molar ratio of 1:0.5-2:0-2.

4. The method for preparing a CIS or CIGS thin film according to claim 1, wherein the solvent is selected from water, alcohol and acetone.

5. The method for preparing a CIS or CIGS thin film according to claim 1, wherein the binder is selected from ethyl cellulose, palmitic acid, polyethylene glycol, polypropylene glycol, polypropylene carbonate, polyvinyl acetate or a mixture thereof.

6. The method for preparing a CIS or CIGS thin film according to claim 1, wherein a dispersant is further added in said mixing the Cu, In and Ga precursors in the solvent and adding the polymer binder.

7. The method for preparing a CIS or CIGS thin film according to claim 6, wherein the dispersant is selected from α-terpineol, ethylene glycol, thioacetamide, ethylenediamine, monoethyleneamine or a mixture thereof.

8. The method for preparing a CIS or CIGS thin film according to claim 1, wherein Na, K, Ni, P, As, Sb, Bi or a combination thereof is added as a dopant in said mixing the Cu, In and Ga precursors in the solvent and adding the polymer binder or in said coating the obtained CIG precursor paste or ink on the conductive substrate.

9. The method for preparing a CIS or CIGS thin film according to claim 1, wherein the paste or ink is coated by doctor blade coating, spin coating, screen printing or spraying.

10. The method for preparing a CIS or CIGS thin film according to claim 1, wherein, in said and said coating the obtained CIG precursor paste or ink on the conductive substrate and heat-treating the same, the heat treatment is performed at 200-900° C.

11. The method for preparing a CIS or CIGS thin film according to claim 1, wherein, in said heat-treating the CIG mixed oxide thin film, the heat treatment is performed independently or sequentially under hydrogen or sulfur-containing gas atmosphere.

12. The method for preparing a CIS or CIGS thin film according to claim 1, wherein, in said heat-treating the CIG mixed oxide thin film, the hydrogen or the hydrogen or sulfur-containing gas is selected from H₂, H₂S, S vapor or a mixture thereof with an inert gas.

13. The method for preparing a CIS or CIGS thin film according to claim 1, wherein, in said heat-treating the CIG mixed oxide thin film, the heat treatment is performed at 400-900° C.

14. The method for preparing a CIS or CIGS thin film according to claim 1, wherein, in said heat-treating the reduced or sulfurized CIG mixed thin film, the selenium-containing gas is selected from H₂Se, Se vapor or a mixture thereof with an inert gas.

15. The method for preparing a CIS or CIGS thin film according to claim 1, wherein, in said heat-treating the reduced or sulfurized CIG mixed thin film, the heat treatment is performed at 400-900° C.

16. A copper indium selenide (CIS) or copper indium gallium selenide (CIGS) thin film for a solar cell prepared by the method for preparing a CIS or CIGS thin film according to claim 1 and having 1 at % or less residual carbon.
